(19) United States
(12) Patent Application Publication
(10) Pub. No.: US 2025/0245399 A1
(43) Pub. Date: Jul. 31, 2025

(54) METHODS AND MODULES FOR CO OPTIMIZATION OF DEEP NEURAL NETWORK ACCELERATORS USING ROBUSTNESS

(71) Applicant: HUAWEI TECHNOLOGIES CO., LTD., Shenzhen (CN)

(72) Inventors: Bahador RASHIDI, Edmonton (CA); Chao Gao, Edmonton (CA); Di Niu, Edmonton (CA); Shan Lu, Edmonton (CA)

(21) Appl. No.: 18/428,093

(22) Filed: Jan. 31, 2024

(51) Int. Cl. G06F 30/27

(52) U.S. Cl. CPC G06F 30/27

(57) ABSTRACT

Methods and modules may comprise obtaining two or more hardware configurations for an accelerator, obtaining two or more first software mappings for the accelerator, executing a series of first simulations for each combination of each of the two or more hardware configurations with each of the two or more first software mappings, wherein power and latency is measured in each of the first simulations, and generating a first robustness metric for each hardware configuration, the robustness metric representing a cross dependency of power and latency in the first simulations. The robustness metric may be used for hardware and software co-exploration to enable a configuration to improved performance for future and/or unseen deep neural network or convolutional neural network applications.

### TECHNICAL FIELD

The present disclosure pertains generally to methods and modules relating to deep neural networks and in particular methods and modules for hardware and software co-exploration using a robustness parameter.

### BACKGROUND

Deep neural networks (DNNs) may be used in a variety of diverse applications such as for computer vision, natural language processing, autonomous driving, and/or the like. DNNs may be based on tensor computations, where tensors are data represented and processed in the form of multi-dimensional arrays. Typically, a DNN comprises multiple layers of tensor operators, where each operator performs multiple basic tensor computations, such as general matrix multiply (GEMM), general matrix-vector multiplication (GEMV), convolution (CONV), and/or the like.

Increasingly intensive and high complexity of tensor computations of DNNs may overwhelm general-purpose processors, such as central processing units (CPUs), graphics processing units (GPUs), and/or the like. Specialized hardware accelerators, such as neural network accelerators may be used to speed up the execution of DNN computations, which may involve a large amount of tensor computations. These accelerators may provide fast execution by taking advantage of parallel computation while preserving high energy efficiency. Consequently, the success of end-to-end artificial (AI) acceleration heavily relies upon not only hardware design, but also on the effectiveness of software mapping compilation for a specific input DNN.

### SUMMARY

Embodiments herein provide methods and modules relating to hardware and software co-exploration for neural networks using a robustness parameter to provide a reliable way to quantify how a hardware design market life can be expanded. Hardware and software co-optimization solutions provided herein may provide rigorous exploration for finding hardware and software designs to reduced overfitting to DNN or convolutional neural network applications. A hardware robustness metric may be used to quantify hardware sensitivity to various software mapping choices and may relate it to hardware design generalizability to future and/or unseen applications.

According to one aspect of this disclosure, a method comprises: obtaining two or more hardware configurations for an accelerator; obtaining two or more first software mappings for the accelerator; executing a series of first simulations for each combination of each of the two or more hardware configurations with each of the two or more first software mappings, wherein power and latency is measured in each of the first simulations; and generating a first robustness metric for each hardware configuration, the robustness metric representing a cross-dependency of power and latency in the first simulations.

In some embodiments, the method further comprises selecting the hardware configuration having the highest first robustness metric.

In some embodiments, the method further comprises selecting the hardware configuration based on the first robustness metric and surface area of the hardware configuration.

In some embodiments, the method further comprises identifying the first software mapping having the lowest total latency in the first simulations, wherein a simulation may refer to using a reliable simulator for a hardware topology of an accelerator under study that permits simulation of performance (e.g. latency, power, area, etc.) for a particular hardware design and a particular software mapping using a reliable software mapping exploration tool.

In some embodiments, the number of hardware configurations and the number of first software mappings obtained is based on an exploration budget.

In some embodiments, the method further comprises providing the first robustness metrics to a multi-objective Bayesian optimization method for evaluating hardware configurations based on associated first robustness metrics.

In some embodiments, the method further comprises selecting a first subset of hardware configurations comprising two or more of the hardware configurations; obtaining two or more second software mappings for the accelerator; performing a second simulation for each combination of each hardware configuration of the first subset with each of the two or more second software mappings, wherein power and latency is measured in each of the second simulations; and generating a second robustness metric for each of hardware configurations of the first subset, the second robustness metric representing cross-dependency of power and latency in the second simulations.

In some embodiments, the hardware configurations of the first subset are selected based on the first robustness metrics.

In some embodiments, the two or more second software mappings are selected based on measured latency relating to the two or more first software mappings in the first simulations.

In some embodiments, the method further comprises selecting the hardware configuration of the first subset having the highest second robustness metric.

In a broad aspect of the present disclosure, one or more non-transitory computer-readable storage modules comprising computer-executable instructions, wherein the instructions, when executed cause a processing structure to perform actions comprises: obtaining two or more hardware configurations for an accelerator; obtaining two or more first software mappings for the accelerator; executing a series of first simulations for each combination of each of the two or more hardware configurations with each of the two or more first software mappings, wherein power and latency is measured in each of the first simulations; and generating a first robustness metric for each hardware configuration, the robustness metric representing a cross-dependency of power and latency in the first simulations.

In some embodiments, the actions further comprise selecting the hardware configuration having the highest first robustness metric.

In some embodiments, the actions further comprise selecting the hardware configuration based on the first robustness metric and surface area of the hardware configuration.

In some embodiments, the actions further comprise identifying the first software mapping having the lowest total latency in the first simulations.

In some embodiments, the number of hardware configurations and the number of first software mappings obtained is based on an exploration budget.

In some embodiments, the actions further comprise providing the first robustness metrics to a multi-objective Bayesian optimization method for evaluating hardware configurations based on associated first robustness metrics.

In some embodiments, the actions further comprise: selecting a first subset of hardware configurations comprising two or more of the hardware configurations; obtaining two or more second software mappings for the accelerator; performing a second simulation for each combination of each hardware configuration of the first subset with each of the two or more second software mappings, wherein power and latency is measured in each of the second simulations; and generating a second robustness metric for each of hardware configurations of the first subset, the second robustness metric representing cross-dependency of power and latency in the second simulations.

In some embodiments, the hardware configurations of the first subset are selected based on the first robustness metrics.

In some embodiments, the two or more second software mappings are selected based on measured latency relating to the two or more first software mappings in the first simulations

In some embodiments, the actions further comprise selecting the hardware configuration of the first subset having the highest second robustness metric.

### BRIEF DESCRIPTION OF THE DRAWINGS

For a more complete understanding of the disclosure, reference is made to the following description and accompanying drawings, in which:

FIG. 1 is a schematic illustrating a general design template of an exemplary 2-dimensional spatial accelerator;

FIG. 2 is a schematic illustrating a framework of a hardware and software co-exploration accelerator;

FIG. 2A is a schematic illustrating an embodiment of a hardware design configuration in the framework of FIG. 2;

FIG. 3A is a graph illustrating software mapping objective convergence during search and indication of two promising software mapping choices;

FIG. 3B is a schematic illustrating latency and power for two hypothetical scenarios;

FIG. 3C is a graph illustrating analytical function F(θ) to quantify the power variation behavior with respect to latency decrease in an embodiment of a robustness metric R=Δ(1+F(θ));

FIG. 4 is a schematic illustrating frameworks of hardware and software co-exploration accelerators with and without using hardware robustness;

FIG. 4A is a schematic illustrating an embodiment of a hardware design configuration in the framework of FIG. 4;

FIG. 4B is a schematic illustrating an embodiment of a hardware design configuration in the framework of FIG. 4;

FIG. 5 is a schematic illustrating a high-fidelity update strategy for integrating the robustness into HW/SW co-optimization pipeline;

FIG. 6 is a schematic diagram showing a simplified hardware structure of a computing device;

FIG. 7 is a schematic diagram showing a simplified software architecture of a computing device; and

FIG. 8 is a block diagram of a method according to some embodiments of this disclosure.

Throughout the appended drawings, like features are identified by like reference numerals.

### DETAILED DESCRIPTION

Unless otherwise defined, all technical and scientific terms used herein generally have the same meaning as commonly understood by one of ordinary skill in the art to which this disclosure pertains. Exemplary terms are defined below for ease in understanding the subject matter of the present disclosure.

The term “a” or “an” refers to one or more of that entity; for example, “a terminal” refers to one or more terminals or at least one terminal. As such, the terms “a” (or “an”), “one or more” and “at least one” are used interchangeably herein. In addition, reference to an element or feature by the indefinite article “a” or “an” does not exclude the possibility that more than one of the elements or features are present, unless the context clearly requires that there is one and only one of the elements. Furthermore, reference to a feature in the plurality (e.g., systems), unless clearly intended, does not mean that the systems or methods disclosed herein must comprise a plurality.

The expression “and/or” refers to and encompasses any and all possible combinations of one or more of the associated listed items (e.g. one or the other, or both), as well as the lack of combinations when interrupted in the alternative (or).

Deep neural networks (DNNs) may be used in a variety of diverse applications such as for computer vision, natural language processing, autonomous driving, and/or the like. DNNs may be based on tensor computations, where tensors are data represented and processed in the form of multi-dimensional arrays. Typically, a DNN comprises multiple layers of tensor operators, where each operator performs multiple basic tensor computations, such as general matrix multiply (GEMM), general matrix-vector multiplication (GEMV), convolution (CONV), and/or the like. While DNNs are generally referred to herein, the embodiments disclosed herein may be applied to different types of artificial intelligence processing, including DNNs, convolutional neural networks, recurrent neural networks, perceptron, feed-forward neural networks, multilayer perceptron, radial basis functional neural networks, long short-term memory, sequence-to-sequence models, and/or the like.

Increasingly intensive and high complexity of tensor computations of DNNs may overwhelm general-purpose processors, such as central processing units (CPUs), graphics processing units (GPUs), and/or the like. Specialized hardware accelerators, such as neural network accelerators may be used to speed up the execution of DNN computations, which may involve a large amount of tensor computations. These accelerators may provide fast execution by taking advantage of parallel computation while preserving high energy efficiency. Consequently, the success of end-to-end artificial (AI) acceleration heavily relies upon not only hardware design, but also on the effectiveness of software mapping compilation for a specific input DNN.

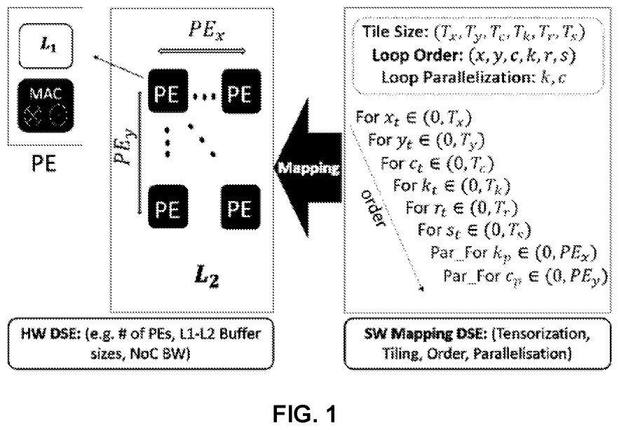

Customized hardware accelerators may be designed for providing real-time processing of DNNs. Such accelerators are generally spatial in nature wherein they use an array of interconnected processing elements (PEs) for parallelism. The internal dataflow between PEs may be optimized using network-on-chips (NoCs) for efficient data reuse (for example, for input activations, weights, output activations, and/or the like). Such designs may reduce memory accesses, as one of the most energy consuming actions on chip, thus contributes to high energy-efficiency. FIG. 1 illustrates a general design template of an exemplary 2-dimensional spatial accelerator where key design choices comprise number of processing elements (PEs) in X and Y axis (PEₓ, PE_{y}), private scratch pad size (L₁), global memory size (L₂) and network on-chip bandwidth (NoCBW). FIG. 1 illustrates the 2-dimensional spatial accelerator hardware architecture and software mapping of a convolution tensor on the hardware.

Once hardware design (i.e. PE shape, buffers, bandwidth sizes, and/or the like) is determined and fixed, for a given input DNN workload (e.g. convolution), the remaining task is optimizing software mapping choices. As shown in FIG. 1, every tensor computation may be represented as a nested loop structure and a mapping choice for that is deemed as a set of specific parameters belong to software mapping design primitives. For example, commonly used primitives for software mapping include loop split, loop reorder, loop fuse, loop tiling, and/or the like. As shown in FIG. 1, software mapping design space may comprise a particular set of scheduling primitives that may be applied in a specific order to the original loop representation such that the smallest computation unite (e.g. inner-most loop) can be mapped directly to certain hardware resources spatially or temporally.

Different scheduling choices may result in large variations in time and energy efficiency. Generally, tensor software (SW) mapping generation largely relies upon manually optimized, high-performance tensor kernel libraries. However, the development of manual operator-level libraries is not only laborious but may also be difficult to maintain as it demands timely updates whenever there are changes to the associated hardware (HW). Auto-scheduling frameworks aiming at automatically synthesizing efficient software mapping for various hardware targets may be used to address these issues. These frameworks generally assume that DNNs as programs of domain specific languages (DSLs), then introduce a set of optimization primitives for a compiler to translate the high-level DNN DSL into low-level code. This process may be referred to as scheduling.

Evaluation and selection of preferred software mappings may depend upon how the hardware is designed and what parameter values are selected for hardware components. While AI hardware and software may be generally updated separately, results may be suboptimal, resulting into compounded end-to-end performance loss when jointly deployed. To address these limitations, HW/SW co-exploration approaches may be used. HW/SW co-design generally comprises a bi-level exploration, since the SW mapping choices may be affected by selected HW configurations (e.g. #of PEs, L1 and L2), and the latter must be sampled first such that it informs a constraint for a SW mapping parameters search space. This sequential dependency suggests a bi-level optimization scheme.

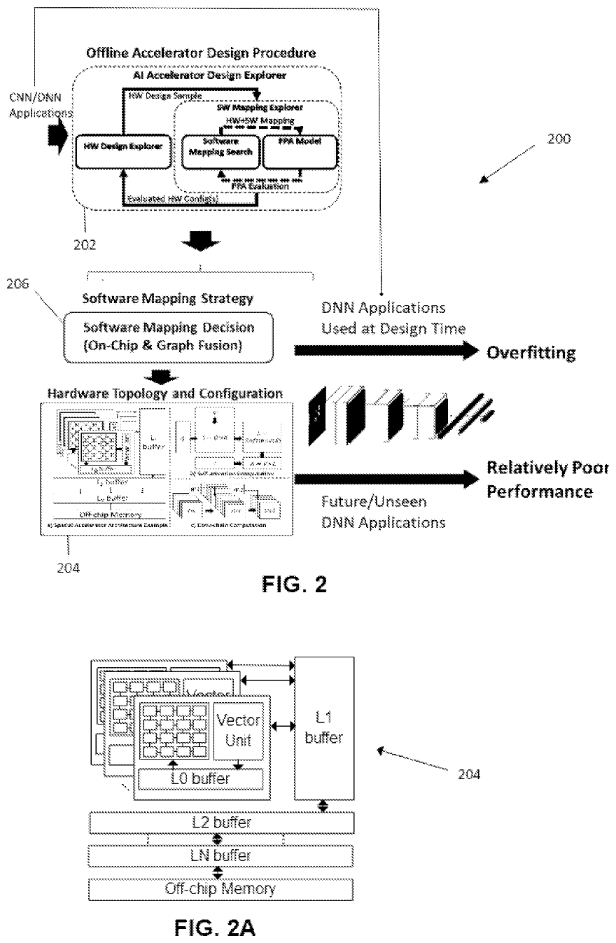

FIG. 2 illustrates a flow diagram of HW/SW co-exploration framework 200. In the outer-level 202, a HW design configuration 204 is sampled and is passed to the inner-level for SW mapping exploration 206. When a specific HW configuration 204 and its corresponding SW mapping 206 is determined, a performance-power-area (PPA) estimator may be used to evaluate the quality of a specific HW/SW candidate.

An issue resulting from the above described holistic solution is that a generated hardware may be overly specific or overfit to a given input deep neural network model, as illustrated in FIG. 2. Such overfitting might be alleviated by joint-optimization with a large set of given DNNs and assigning large exploration budget to find near global optimum joint design. However, this fundamental issue cannot be completely addressed no matter how large a set of DNNs is used for co-design or co-optimization, and the shortcoming can be more severe as new DNNs are being continually developed and deployed by AI researchers and industry members. With respect to this important aspect which impacts profitability of accelerator designs, in some embodiments disclosed herein, methods and modules provide a solution that systematically considers HW design robustness and ensures generalizability to future and/or yet unseen DNN-related applications. Such an approach may provide solutions that increase the effective life of the AI cores use in applications, products and systems in the market.

In some embodiments disclosed herein, methods and modules hardware and software co-design and mapping comprises a hardware design robustness metric, which may be relevant for on-chip mapping schedules. Use of the hardware design robustness metric in embodiments disclosed herein provide hardware generalizability to new and unseen, as at the time of co-design, DNN applications, which may provide cloud or edge devices comprising AI cores having a longer period of performance competitiveness by extending the life of the hardware configuration in the market.

While a person of skill would understand there to be many different ways to measure robustness, in some embodiments disclosed herein, a robustness metric for use during co-optimization may be used with Multi-Objective Bayesian Optimization (MOBO), which may be effectively used for some accelerator co-designs generally. A full-fledged integration of the robustness metric disclosed herein with MOBO may be used to initially identify non-robust hardware designs and discard them from the exploration process.

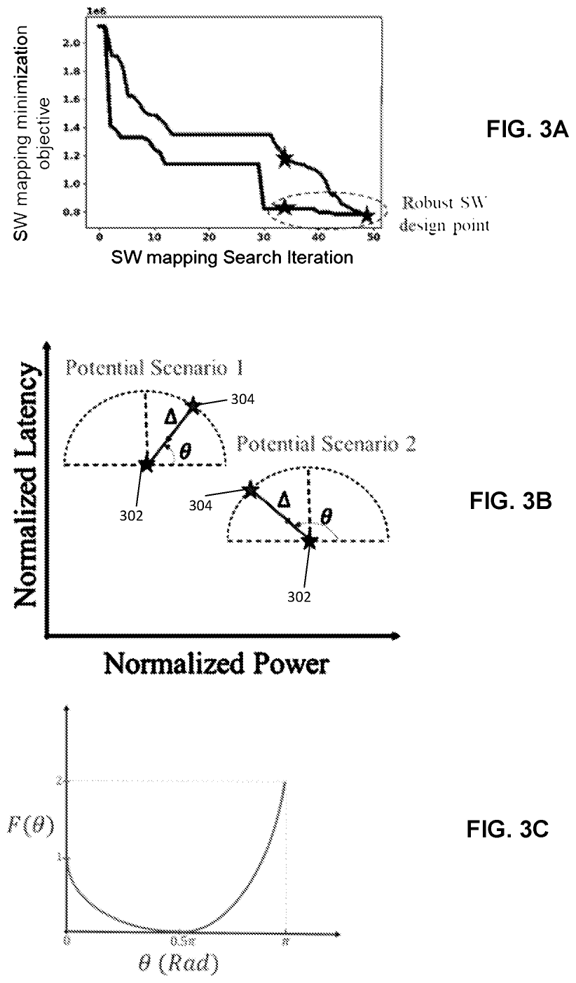

The robustness metric R may be used to systematically quantify the generalizability of hardware configurations during HW/SW co-exploration and alleviate overfitting. Hardware h may be deemed robust when both latency (i.e. performance) and power have negligible variations with software mappings comprising a range of different budgets. Software mapping exploration with different budgets may lead to a set of different “promising” on-chip software mapping choices. FIG. 3A illustrates software minimization loss for a given hardware configuration during a software mapping search. In particular, a software mapping choice may be determined to be “promising” if its corresponding software mapping objective (e.g. latency) value is less than (1−α) right-tail percentile of all objective values generated in FIG. 3A.

The robustness metric may use a geometric approach and may be expressed as follows:

$$R = Δ ( 1 + F ( θ ) ) , \qquad ( 1 )$$

where Δ is the 2-norm distance of the two selected candidates as in FIG. 3A. θ is the linear approaching angle of the α^{th}-percentile mapping choice to the best-found software mapping.

As shown in FIG. 3B, by design, Δ=0 implies ideal robustness. However, if Δ>0, further consideration of the coupled correlation behavior of latency and power may be done by adding the second term (1+F(θ)) in equation (1). Further to FIG. 3B, if θ=π/2, latency is decreased by Δ and power was not changed, which implies power robustness but latency non-robustness with value of Δ. To incorporate relation into the calculation:

$$F ( θ ) = \frac{6}{{π}^{2}} {θ}^{2} - \frac{5}{π} θ + 1 , \qquad ( 2 )$$

As shown in FIG. 3C, when θ=π/2, F(π/2)=0, therefore R=Δ(1+0)=Δ. For the scenario when the ‘orange’ point is in first circle quarter, 0≤F(0≤θ≤π/2)≤1, the robustness metric range is Δ≤R≤2Δ. That means if θ=0, power value change is Δ and F(0)=1, hence R=Δ(1+1)=2Δ. On the other hand, when a first point 304 is in the second circle quarter, 0≤F(π/2≤θ≤π)≤2, hence the robustness metric is further penalized to be within Δ≤R≤3Δ. This specifically implies our design prefer 0≤θ≤π/2 more than π/2≤θ≤π. The intuition here is that from first point 304 to second point 302, power was increased, which is not favorable by our design in comparison to the other case (first circle quarter) when both latency and power decrease.

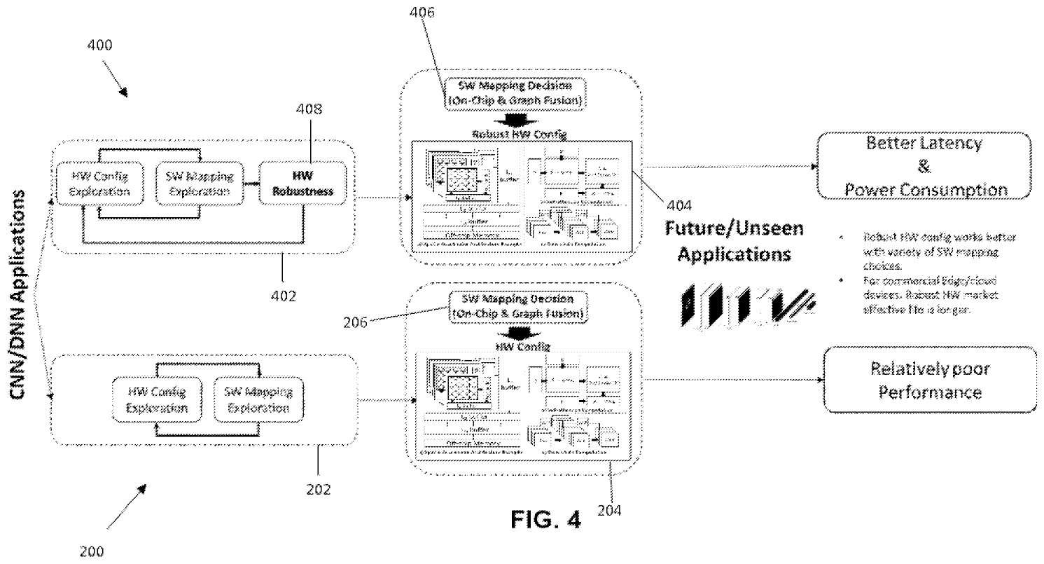

FIG. 4 illustrates a flow diagram of HW/SW co-exploration framework 400 comprising hardware robustness metric 408. In the outer-level 402, a HW design configuration 404 is sampled and is passed to the inner-level for SW mapping exploration 206. When a specific HW configuration 404 and its corresponding SW mapping 406 is determined, a performance-power-area (PPA) estimator may be used to evaluate the quality of a specific HW/SW candidate.

In some embodiments disclosed herein, hardware robustness may be represented and/or quantified in terms of a metric R, i.e., robustness, which in co-exploration may enhance the generalization of hardware to future and/or unseen workloads and may boost the overall quality of the co-exploration process.

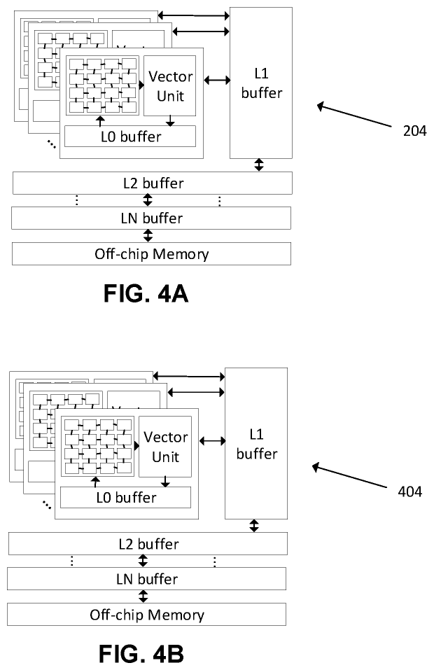

Referring to FIG. 5, embodiments of the present disclosure provide a high-fidelity update strategy for integrating the concept of hardware design generalizability in the form of robustness into a HW/SW co-optimization pipeline. At the end of each exploration trial 501, 502 and 50N, a high-fidelity distribution D may be generated empirically and used to select top-performing and robust hardware configurations among a batch of candidates. This high-fidelity update strategy ensures the high-fidelity hardware configurations are used for the hardware design exploration.

The non-robustness (i.e. sensitivity) metric R may be determined at the end of each trial 501, 502 and 50N for each of hardware configuration in the sampled batch. Particular objectives may be then used for co-exploration. For example, four-dimensional multi-objectives of performance, power, area and robustness may be used as the co-exploration objective of each HW/SW pair.

The above described high-fidelity update strategy may assess the hardware samples by using the fidelity scalar, v_{ParEGO}, which may be expressed as:

$${v}_{ParEGO} = {max}_{j ∈ 1 , 2 , 3 , 4} ( {w}_{j} {y}_{j} ) + ρ {Y}^{T} W$$

The L2-norm distance, d=∥v_{ParEGO}−v_{ParEGO}^{Best}∥₂ may be measured for each hardware configuration, where v_{ParEGO}^{Best} is the up-to-date smallest fidelity scalar value by the current iteration. The upper update limit (UUL) may be used as the selection threshold for high-fidelity HW configurations such that HW configurations with d≤UUL are selected to update the model for next sampling. The d of these high-fidelity hardware configurations is added to a set D. UUL may be updated at each iteration as α-percentile of D, with a confidence parameter, such as of 95% by default as a common threshold in statistics. D is empirically updated with new high-fidelity hardware configurations and thus UUL tends to decrease, making the selection criterion stricter as MOBO progress towards higher trials. Therefore, the above described high-fidelity update strategy ensures that higher fidelity hardware configurations will be selected as more iterations advance, significantly increasing the probability and efficiency to find the global optimal solution.

The effect of metric R on HW/SW a co-exploration process may be two-fold: (1) R is considered as a co-exploration objective and the co-exploration results in sample hardware configurations with better generalizability as iterations advances; and (2) a high-fidelity update mechanism incorporates R when generating high-fidelity metric. As a result, for every evaluated hardware at the end of one iteration of exploration, only samples who are selected based on UUL are deemed as high-fidelity and are used for an upcoming exploration.

As used herein, a “device” is a term of explanation referring to a hardware structure such as a circuitry implemented using technologies such as electrical and/or optical technologies (and with more specific examples of semiconductors) for performing defined operations or processing. A “device” may alternatively refer to the combination of a hardware structure and a software structure, wherein the hardware structure may be implemented using technologies such as electrical and/or optical technologies (and with more specific examples of semiconductors) in a general manner for performing defined operations or processing according to the software structure in the form of a set of instructions stored in one or more non-transitory, computer-readable storage devices or media.

As used herein, the device may be a part of an apparatus, a system, and/or the like, wherein the device may be coupled to or integrated with other parts of the apparatus, or system such that the combination thereof forms the apparatus, or system.

The device executes a process for performing. Herein, a process has a general meaning equivalent to that of a method, and does not necessarily correspond to the concept of computing process (which is the instance of a computer program being executed). More specifically, a process herein is a defined method implemented using hardware components for process data. A process may comprise or use one or more functions for processing data as designed. Herein, a function is a defined sub-process or sub-method for computing, calculating, or otherwise processing input data in a defined manner and generating or otherwise producing output data.

As those skilled in the art will appreciate, the method disclosed herein may be implemented as one or more software and/or firmware programs having necessary computer-executable code or instructions and stored in one or more non-transitory computer-readable storage devices or media which may be any volatile and/or non-volatile, non-removable or removable storage devices such as RAM, ROM, EEPROM, solid-state memory devices, hard disks, CDs, DVDs, flash memory devices, and/or the like. The device may read the computer-executable code from the storage devices and execute the computer-executable code to perform the methods disclosed herein.

Alternatively, the methods disclosed herein may be implemented as one or more hardware structures having necessary electrical and/or optical components, circuits, logic gates, integrated circuit (IC) chips, and/or the like.

The devices may be computing devices that may be portable and/or non-portable computing devices such as laptop computers, tablets, smartphones, Personal Digital Assistants (PDAs), desktop computers, smart devices, and/or the like. Each computing device may execute one or more client application programs which sometimes may be called “apps”.

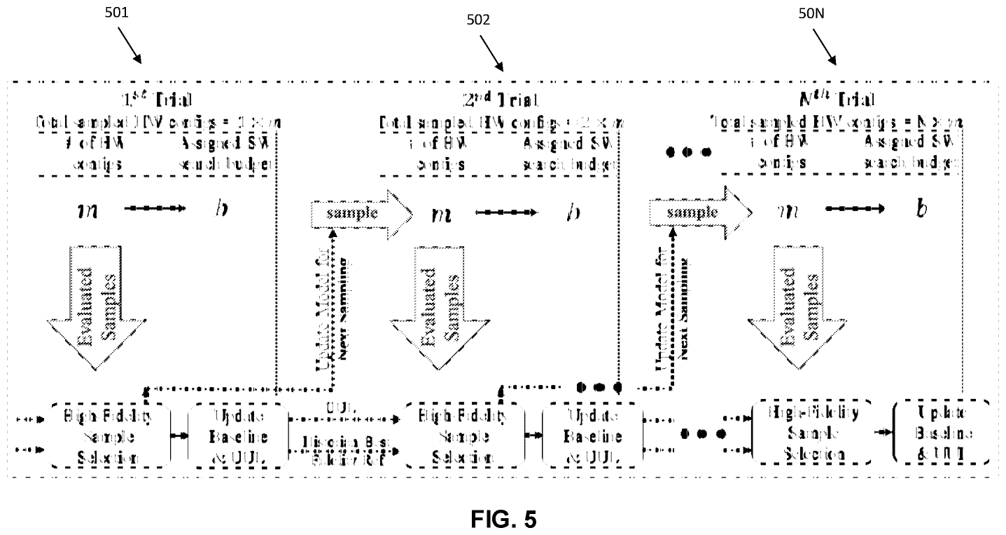

Generally, the computing devices comprise similar hardware structures such as hardware structure 620 shown in FIG. 6. As shown, the hardware structure 620 comprises a processing structure 622, a controlling structure 624, one or more non-transitory computer-readable memory or storage devices 626, a network interface 628, an input interface 630, and an output interface 632, functionally interconnected by a system bus 638. The hardware structure 620 may also comprise other components 634 coupled to the system bus 638.

The processing structure 622 may be one or more single-core or multiple-core computing processors, generally referred to as central processing units (CPUs), such as INTEL® microprocessors (INTEL is a registered trademark of Intel Corp., Santa Clara, CA, USA), AMD® microprocessors (AMD is a registered trademark of Advanced Micro Devices Inc., Sunnyvale, CA, USA), ARM® microprocessors (ARM is a registered trademark of Arm Ltd., Cambridge, UK) manufactured by a variety of manufactures such as Qualcomm of San Diego, California, USA, under the ARM® architecture, or the like. When the processing structure 622 comprises a plurality of processors, the processors thereof may collaborate via a specialized circuit such as a specialized bus or via the system bus 638.

The processing structure 622 may also comprise one or more real-time processors, programmable logic controllers (PLCs), microcontroller units (MCUs), μ-controllers (UCs), specialized/customized processors, hardware accelerators, and/or controlling circuits (also denoted “controllers”) using, for example, field-programmable gate array (FPGA) or application-specific integrated circuit (ASIC) technologies, and/or the like. In some embodiments, the processing structure includes a CPU (otherwise referred to as a host processor) and a specialized hardware accelerator which includes circuitry configured to perform computations of neural networks such as tensor multiplication, matrix multiplication, and the like. The host processor may offload some computations to the hardware accelerator to perform computation operations of neural network. Examples of a hardware accelerator include a graphics processing unit (GPU), Neural Processing Unit (NPU), and Tensor Process Unit (TPU). In some embodiments, the host processors and the hardware accelerators (such as the GPUs, NPUs, and/or TPUs) may be generally considered processors.

Generally, the processing structure 622 comprises necessary circuitry implemented using technologies such as electrical and/or optical hardware components for executing transformer related processes.

For example, the processing structure 622 may comprise logic gates implemented by semiconductors to perform various computations, calculations, and/or processing. Examples of logic gates include AND gate, OR gate, XOR (exclusive OR) gate, and NOT gate, each of which takes one or more inputs and generates or otherwise produces an output therefrom based on the logic implemented therein. For example, a NOT gate receives an input (for example, a high voltage, a state with electrical current, a state with an emitted light, or the like), inverts the input (for example, forming a low voltage, a state with no electrical current, a state with no light, or the like), and output the inverted input as the output.

While the inputs and outputs of the logic gates are generally physical signals and the logics or processing thereof are tangible operations with physical results (for example, outputs of physical signals), the inputs and outputs thereof are generally described using numerals (for example, numerals “0” and “1”) and the operations thereof are generally described as “computing” (which is how the “computer” or “computing device” is named) or “calculation”, or more generally, “processing”, for generating or producing the outputs from the inputs thereof.

Sophisticated combinations of logic gates in the form of a circuitry of logic gates, such as the processing structure 622, may be formed using a plurality of AND, OR, XOR, and/or NOT gates. Such combinations of logic gates may be implemented using individual semiconductors, or more often be implemented as integrated circuits (ICs).

A circuitry of logic gates may be “hard-wired” circuitry which, once designed, may only perform the designed functions. In this example, the processes and functions thereof are “hard-coded” in the circuitry.

With the advance of technologies, it is often that a circuitry of logic gates such as the processing structure 622 may be alternatively designed in a general manner so that it may perform various processes and functions according to a set of “programmed” instructions implemented as firmware and/or software and stored in one or more non-transitory computer-readable storage devices or media. In this example, the circuitry of logic gates such as the processing structure 622 is usually of no use without meaningful firmware and/or software.

Of course, those skilled in the art will appreciate that a process or a function (and thus the processor) may be implemented using other technologies such as analog technologies.

Referring back to FIG. 6, the controlling structure 624 comprises one or more controlling circuits, such as graphic controllers, input/output chipsets and the like, for coordinating operations of various hardware components and modules of the computing device.

The memory 626 comprises one or more storage devices or media accessible by the processing structure 622 and the controlling structure 624 for reading and/or storing instructions for the processing structure 622 to execute, and for reading and/or storing data, including input data and data generated by the processing structure 622 and the controlling structure 624. The memory 626 may be volatile and/or non-volatile, non-removable or removable memory such as RAM, ROM, EEPROM, solid-state memory, hard disks, CD, DVD, flash memory, or the like.

The input interface 630 comprises one or more input modules for one or more users to input data via, for example, touch-sensitive screen, touch-sensitive whiteboard, touch-pad, keyboards, computer mouse, trackball, microphone, scanners, cameras, and/or the like. The input interface 630 may be a physically integrated part of the computing device (for example, the touch-pad of a laptop computer or the touch-sensitive screen of a tablet), or may be a device physically separate from, but functionally coupled to, other components of the computing device (for example, a computer mouse). The input interface 630, in some implementation, may be integrated with a display output to form a touch-sensitive screen or touch-sensitive whiteboard.

The output interface 632 comprises one or more output modules for output data to a user. Examples of the output modules comprise displays (such as monitors, LCD displays, LED displays, projectors, and the like), speakers, printers, virtual reality (VR) headsets, augmented reality (AR) goggles, and/or the like. The output interface 632 may be a physically integrated part of the computing device (for example, the display of a laptop computer or tablet), or may be a device physically separate from but functionally coupled to other components of the computing device (for example, the monitor of a desktop computer).

The system bus 638 interconnects various components 622 to 634 enabling them to transmit and receive data and control signals to and from each other.

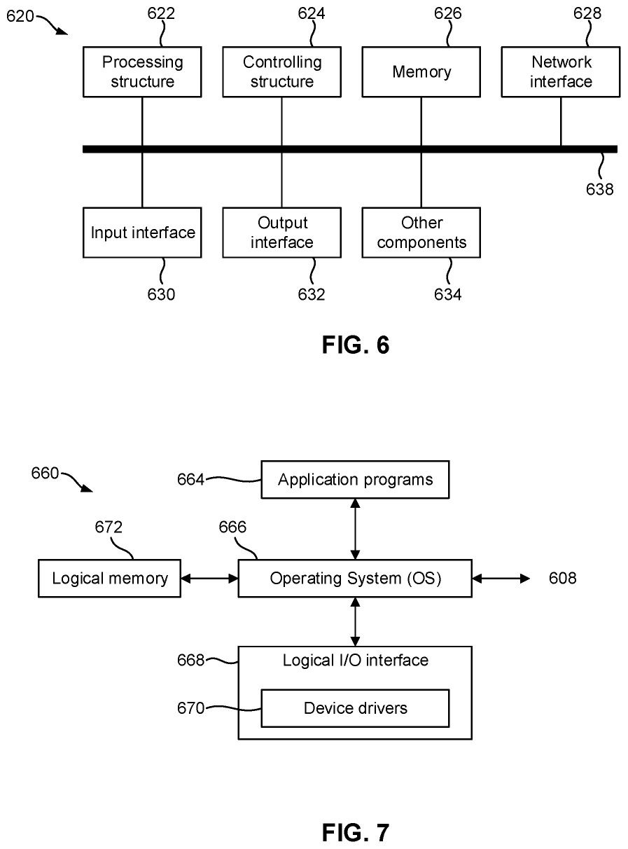

FIG. 7 shows a simplified software architecture 660 of the computing device. The software architecture 660 comprises one or more application programs 664, an operating system 666, a logical input/output (I/O) interface 668, and a logical memory 672. The one or more application programs 664, operating system 666, and logical I/O interface 668 are generally implemented as computer-executable instructions or code in the form of software programs or firmware programs stored in the logical memory 672 which may be executed by the processing structure 622.

The one or more application programs 664 executed by or run by the processing structure 622 for performing various tasks such as the methods disclosed herein.

The operating system 666 manages various hardware components of the computing device 602 or 604 via the logical I/O interface 668, manages the logical memory 672, and manages and supports the application programs 664. The operating system 666 is also in communication with other computing devices (not shown) via the network 608 to allow application programs 664 to communicate with those running on other computing devices. As those skilled in the art will appreciate, the operating system 666 may be any suitable operating system such as MICROSOFT® WINDOWS® (MICROSOFT and WINDOWS are registered trademarks of the Microsoft Corp., Redmond, WA, USA), APPLE® OS X, APPLE® iOS (APPLE is a registered trademark of Apple Inc., Cupertino, CA, USA), Linux, ANDROID® (ANDROID is a registered trademark of Google LLC, Mountain View, CA, USA), or the like. The computing devices may all have the same operating system, or may have different operating systems.

The logical I/O interface 668 comprises one or more device drivers 670 for communicating with respective input and output interfaces 630 and 632 for receiving data therefrom and sending data thereto. Received data may be sent to the one or more application programs 664 for being processed by one or more application programs 664. Data generated by the application programs 664 may be sent to the logical I/O interface 668 for outputting to various output devices (via the output interface 632).

The logical memory 672 is a logical mapping of the physical memory 626 for facilitating the application programs 664 to access. In this embodiment, the logical memory 672 comprises a storage memory area that may be mapped to a non-volatile physical memory such as hard disks, solid-state disks, flash drives, and the like, generally for long-term data storage therein. The logical memory 672 also comprises a working memory area that is generally mapped to high-speed, and in some implementations volatile, physical memory such as RAM, generally for application programs 664 to temporarily store data during program execution. For example, an application program 664 may load data from the storage memory area into the working memory area, and may store data generated during its execution into the working memory area. The application program 664 may also store some data into the storage memory area as required or in response to a user's command.

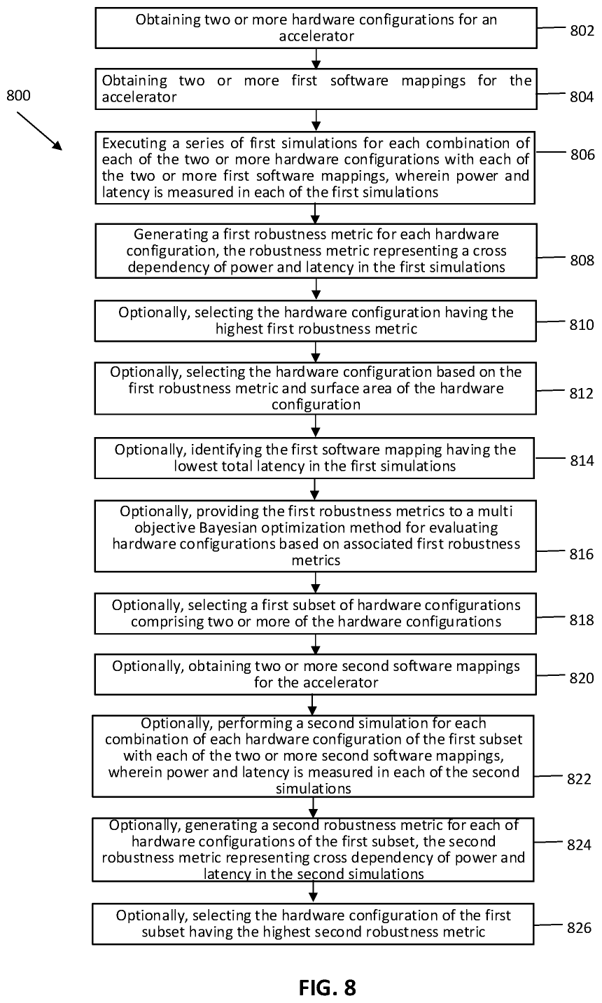

FIG. 8 is a flowchart showing the steps of a method 800 according to some embodiments of the present disclosure. The method 800 begins with obtaining two or more hardware configurations for an accelerator (at step 802). At step 804, the method comprises obtaining two or more first software mappings for the accelerator. At step 806, the method comprises executing a series of first simulations for each combination of each of the two or more hardware configurations with each of the two or more first software mappings, wherein power and latency is measured in each of the first simulations. At step 808, the method comprises generating a first robustness metric for each hardware configuration, the robustness metric representing a cross dependency of power and latency in the first simulations. At step 810, the method comprises, optionally, selecting the hardware configuration having the highest first robustness metric. At step 812, the method comprises, optionally, selecting the hardware configuration based on the first robustness metric and surface area of the hardware configuration. At step 814, the method comprises, optionally, identifying the first software mapping having the lowest total latency in the first simulations. At step 816, the method comprises, optionally, providing the first robustness metrics to a multi objective Bayesian optimization method for evaluating hardware configurations based on associated first robustness metrics. At step 818, the method comprises, optionally, selecting a first subset of hardware configurations comprising two or more of the hardware configurations. At step 820, the method comprises, optionally, obtaining two or more second software mappings for the accelerator. At step 822, the method comprises, optionally, performing a second simulation for each combination of each hardware configuration of the first subset with each of the two or more second software mappings, wherein power and latency is measured in each of the second simulations. At step 824, the method comprises, optionally, generating a second robustness metric for each of hardware configurations of the first subset, the second robustness metric representing cross dependency of power and latency in the second simulations. At step 826, the method comprises, optionally, selecting the hardware configuration of the first subset having the highest second robustness metric.

Embodiments have been described above in conjunctions with aspects of the present invention upon which they may be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

Although the present invention has been described with reference to specific features and embodiments thereof, it is evident that various modifications and combinations may be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A method comprising:
obtaining two or more hardware configurations for an accelerator;
obtaining two or more first software mappings for the accelerator;
executing a series of first simulations for each combination of each of the two or more hardware configurations with each of the two or more first software mappings, wherein power and latency is measured in each of the first simulations; and
generating a first robustness metric for each hardware configuration, the robustness metric representing a cross dependency of power and latency in the first simulations.

2. The method of claim 1, further comprising selecting the hardware configuration having the highest first robustness metric.

3. The method of claim 1, further comprising selecting the hardware configuration based on the first robustness metric and surface area of the hardware configuration.

4. The method of claim 1, further comprising identifying the first software mapping having the lowest total latency in the first simulations.

5. The method of claim 1, wherein the number of hardware configurations and the number of first software mappings obtained is based on an exploration budget.

6. The method of claim 1, further comprising providing the first robustness metrics to a multi objective Bayesian optimization method for evaluating hardware configurations based on associated first robustness metrics.

7. The method of claim 1 further comprising:
selecting a first subset of hardware configurations comprising two or more of the hardware configurations;
obtaining two or more second software mappings for the accelerator;
performing a second simulation for each combination of each hardware configuration of the first subset with each of the two or more second software mappings, wherein power and latency is measured in each of the second simulations; and
generating a second robustness metric for each of hardware configurations of the first subset, the second robustness metric representing cross dependency of power and latency in the second simulations.

8. The method of claim 7, wherein the hardware configurations of the first subset are selected based on the first robustness metrics.

9. The method of claim 7, wherein the two or more second software mappings are selected based on measured latency relating to the two or more first software mappings in the first simulations.

10. The method of claim 7, further comprising selecting the hardware configuration of the first subset having the highest second robustness metric.

11. One or more non transitory computer readable storage modules comprising computer executable instructions, wherein the instructions, when executed cause a processing structure to perform actions comprising:
obtaining two or more hardware configurations for an accelerator;
obtaining two or more first software mappings for the accelerator;
executing a series of first simulations for each combination of each of the two or more hardware configurations with each of the two or more first software mappings, wherein power and latency is measured in each of the first simulations; and
generating a first robustness metric for each hardware configuration, the robustness metric representing a cross dependency of power and latency in the first simulations.

12. The one or more non transitory computer readable storage modules of claim 11, wherein the actions further comprise selecting the hardware configuration having the highest first robustness metric.

13. The one or more non transitory computer readable storage modules of claim 11, wherein the actions further comprise selecting the hardware configuration based on the first robustness metric and surface area of the hardware configuration.

14. The one or more non transitory computer readable storage modules of claim 11, wherein the actions further comprise identifying the first software mapping having the lowest total latency in the first simulations.

15. The one or more non transitory computer readable storage modules of claim 11, wherein the number of hardware configurations and the number of first software mappings obtained is based on an exploration budget.

16. The one or more non transitory computer readable storage modules of claim 11, wherein the actions further comprise providing the first robustness metrics to a multi objective Bayesian optimization method for evaluating hardware configurations based on associated first robustness metrics.

17. The one or more non transitory computer readable storage modules of claim 11, wherein the actions further comprise:
selecting a first subset of hardware configurations comprising two or more of the hardware configurations;
obtaining two or more second software mappings for the accelerator;
performing a second simulation for each combination of each hardware configuration of the first subset with each of the two or more second software mappings, wherein power and latency is measured in each of the second simulations; and
generating a second robustness metric for each of hardware configurations of the first subset, the second robustness metric representing cross dependency of power and latency in the second simulations.

18. The one or more non transitory computer readable storage modules of claim 17, wherein the hardware configurations of the first subset are selected based on the first robustness metrics.

19. The one or more non transitory computer readable storage modules of claim 17, wherein the two or more second software mappings are selected based on measured latency relating to the two or more first software mappings in the first simulations.

20. The one or more non transitory computer readable storage modules of claim 17, wherein the actions further comprise selecting the hardware configuration of the first subset having the highest second robustness metric.
